(19) United States
(12) Patent Application Publication
(10) Pub. No.: US 2025/0004513 A1
(43) Pub. Date: Jan. 2, 2025

(54) LIDAR HEAT DISSIPATION STRUCTURE AND LIDAR

(71) Applicant: INNOVUSION (SUZHOU) CO., LTD., SUZHOU (CN)

(72) Inventors: Guojun LIU, SUZHOU (CN); Lirui LU, SUZHOU (CN); Siwei LUO, SUZHOU (CN); Junwei BAO, SUZHOU (CN)

(73) Assignee: INNOVUSION (SUZHOU) CO., LTD., SUZHOU (CN)

(21) Appl. No.: 18/713,155

(22) PCT Filed: Nov. 21, 2022
(86) PCT No.: PCT/IB2022/061197

§ 371 Date: May 23, 2024

(30) Foreign Application Priority Data
Nov. 24, 2021 (CN) 202122891363.7

(51) Int. Cl. G06F 1/20; G01S 7/481; H05K 7/20

(52) U.S. Cl. CPC G06F 1/20; G01S 7/4813; H05K 7/20409; H05K 7/20481

(57) ABSTRACT

The present utility model discloses a LiDAR heat dissipation structure and a LiDAR. The LiDAR comprises a mainboard, a chip, and a housing. The chip is provided on the mainboard. The heat dissipation structure comprises: a cold plate, the inner surface of the cold plate provided with a temperature equalization structure layer of multi-layer structure attached thereon and the outer surface of the cold plate facing away from the chip provided with a plurality of heat dissipation fins or heat dissipation slots formed thereon; and a heat pipe, fixedly embedded in the cold plate through a thermally conductive structural adhesive, wherein the cold plate couples with the housing to form a sealed cavity in which the mainboard and the chip are provided.

### CROSS-REFERENCE TO RELATED APPLICATIONS

This application claims priority to Chinese Patent Application No. 202122891363.7, filed Nov. 24, 2021, entitled “A HEAT DISSIPATION STRUCTURE FOR LIDAR AND LIDAR,” the content of which is hereby incorporated by reference in its entirety.

### TECHNICAL FIELD

The present utility model relates to the technical field of LiDAR heat dissipation, and in particular to a LiDAR heat dissipation structure and a LiDAR having the heat dissipation structure.

### BACKGROUND

LiDAR (Light Detection and Ranging) is a radar system that emits a laser beam to detect characteristic quantity, such as position and speed, of a target. Its working principle is to transmit a detection signal (a laser beam) to a target, compare the received signal (target echo) reflected from the target to the transmitted signal, and obtain the relevant information of the target with proper processing, such as target distance, orientation, height, speed, attitude, and even shape and other parameters, so as to detect, track and identify the target.

LiDAR integrates a large number of optical, electronic and mechanical components inside, and belongs to opto-mechatronics sensing equipment with high integration and high power density. The United States once analyzed the failures of airborne electronic equipment throughout the year and found that the reasons for the failures are as follows: more than 50% of the failures are caused by all kinds of environmental factors, and 43.58% of the failures of the electronic devices are caused by three environmental factors of temperature, vibration and humidity, in which 22.2% of the failures caused by temperature. The same is true for LiDARs, where temperature is the main potential cause.

Therefore, the quality of the heat dissipation of the LiDAR directly affects the service life and reliability of the LiDAR. In the prior art, the heat dissipation methods of a LiDAR generally include natural heat dissipation and active heat dissipation. The active heat dissipation further includes air-cooling heat dissipation and liquid-cooling heat dissipation. For the air-cooling heat dissipation, additional fans and ventilation holes are necessary which occupy a lot of the limited internal space of the LiDAR, and the fan is prone to vibration during operation and thus generates noise. In addition, since the heat concentration problems of the electronic components inside the LiDAR are usually regional heat concentration and overheat at a certain point, etc., which cannot be solved by the existing heat dissipation methods, it is difficult to effectively ensure that the LiDAR can operate reliably under different working conditions. Although there are solutions to the problem of heat concentration in the prior art, such as making the entire cold plate into a vacuum chamber and rapidly uniformizing the temperature through gas-liquid phase transition, this solution is complicated in process and high in cost. For the problem of overheat at a certain point, although TEC semiconductor heat dissipation is used to solve the problem in the prior art, this solution also has the problem of high cost, and has the additional problems of reliability and additional heat generation, etc. Since the LiDAR is usually installed in a closed space for waterproof and dustproof requirements, the heat dissipation housing of the equipment cannot be in direct contact with the natural air such that the heat transferred from the inside of the LiDAR to the housing cannot be smoothly transferred to the atmosphere. Therefore, the heat dissipation condition is more severe than the conventional natural heat dissipation, and a stronger natural heat dissipation capacity is required.

### SUMMARY

In view of the above-mentioned technical problem, the objective of the present utility model is to provide a LiDAR heat dissipation structure and a LiDAR, which solve the problem to be further optimized and improved that the existing LiDARs use active heat dissipation resulting in complicated structures, high cost, large space occupation and poor heat dissipation capacity.

The technical solutions of the present utility model are as follows.

One objective of the present utility model is to provide a LiDAR heat dissipation structure comprising a mainboard, a chip and a housing, the chip is provided on the mainboard, and the heat dissipation structure comprises:
a cold plate, the inner surface of the cold plate provided with a temperature equalization structure layer of multi-layer structure attached thereon, and the outer surface of the cold plate facing away from the chip provided with a plurality of heat dissipation fins or heat dissipation slots formed thereon; and
a heat pipe, fixedly embedded in the cold plate through a thermally conductive structural adhesive, wherein
the cold plate couples with the housing to form a sealed cavity in which the mainboard and the chip are provided.

Optionally, a recessed embedded portion is provided on a side surface of the cold plate, a gap is formed between an inner wall of the embedded portion and the heat pipe, and the gap is used to be filled with the thermally conductive structural adhesive.

Optionally, the embedded portion is a groove extending along the longitudinal direction of the cold plate, and the depth of the groove is not greater than the thickness of the side wall of the cold plate.

Optionally, a cover plate is provided at the opening of the embedded portion for covering the heat pipe.

Optionally, the temperature equalization structure layer is a graphite layer.

Optionally, the graphite layer is formed by stacking multiple layers of graphite sheets.

Optionally, the housing is made of semi-solid die-cast aluminum alloy.

Optionally, a thermally conductive interface material layer is provided between the chip and the inner surface of the cold plate.

Another objective of the present utility model is to provide a LiDAR comprising the LiDAR heat dissipation structure according to any aspect as described above.

Compared with the prior art, the present utility model has the following advantages:
the LiDAR heat dissipation structure of the present utility model achieves the regional temperature uniformity in a large area through the temperature equalization structure layer and alleviates the problem of overheat at a certain point through the heat pipe fixedly embedded in the cold plate, thereby solving the problem of heat concentration without occupying excessive space. The heat dissipation structure has good heat dissipation performance and ensures that the LiDAR works reliably under different working conditions.

### BRIEF DESCRIPTION OF THE DRAWINGS

The present utility model will be further described below with reference to the accompanying drawings and the embodiments.

FIG. 1 is a schematic cross-sectional structural diagram of a LiDAR heat dissipation structure according to an embodiment of the present utility model.

In the figure: 1. cold plate; 2. heat pipe; 3. graphite layer; 4. thermally conductive structural adhesive; 5. mainboard; 6. chip; 7. thermally conductive interface material layer; and 8. housing.

### DETAILED DESCRIPTION OF EMBODIMENTS

In order to illustrate the objectives, technical solutions and advantages of the present utility model more clearly, the present utility model will be further described in detail below in conjunction with the embodiments and with reference to the accompanying drawings. It should be understood that these descriptions are exemplary, and not intended to limit the scope of the present utility model. Moreover, in the following illustration, the description of well-known structures and techniques are omitted to avoid unnecessarily obscuring the concept of the present utility model.

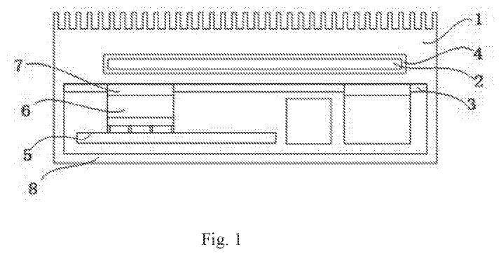

As shown in FIG. 1, in a LiDAR heat dissipation structure according to an embodiment, the LiDAR comprises a mainboard 5, a chip 6, a housing 8, and other components, for example, functional components such as laser and rotating mirror, wherein the mainboard 5, the chip 6 and the functional components such as laser and rotating mirror are provided in the housing 8 in a sealed manner, the housing 8 has a U-shaped structure, the chip 6 is provided on the mainboard 5, the mainboard 5 is an existing conventional PCB, and a plurality of chips 6 may be provided. In FIG. 1 of the present embodiment, one chip 6 is shown as an example. The heat dissipation structure comprises a cold plate 1 and a heat pipe 2. The cold plate 1 is in the shape of a square plate and couples with the housing 8 to form a sealed cavity in which the mainboard 5 and the functional components such as laser and rotating mirror are sealed, with the inner surface of the cold plate 1, i.e., the lower surface of the cold plate 1 as shown in FIG. 1, being provided with a temperature equalization structure layer attached thereon, and the outer surface facing away from the chip 6, i.e., the upper surface of the cold plate 1 as shown in FIG. 1, being provided with a plurality of heat dissipation fins or heat dissipation slots formed thereon. Specifically, the heat pipe 2 is an elongated sheet-like heat pipe 2 extending along the longitudinal direction of the cold plate 1, i.e., the left-right direction as shown in FIG. 1, and is fixedly embedded in the cold plate 1 through a thermally conductive structural adhesive 4. The inner surface of the cold plate 1 is provided with the temperature equalization structure layer attached thereon, thereby solving the problem of regional heat concentration of electronic components inside the LiDAR and achieving the temperature uniformity in a large area. It also solves the problem of process complexity and high cost in the prior art wherein the interior of the cold plate 1 is made into a vacuum cavity and the temperature equalization is achieved by gas-liquid phase transition. By providing the heat pipe 2 inside the cold plate 1, the problem of overheat at a certain point of the electronic components inside the LiDAR is resolved, and the heat of the overheat point is quickly transferred to the cooler and less temperature-sensitive region on the LiDAR. It also solves the problem of high cost, reliability and additional heat in the existing method wherein the heat dissipation is achieved by the TEC semiconductor and the air-cooling heat dissipation device. In addition, the heat pipe 2 is fixedly embedded by the thermally conductive structural adhesive 4, where not only the heat pipe 2 is fixed, but also the contact thermal resistance is reduced. Compared with the conventional method of tin soldering or interference fit, it has simpler process and lower cost. The disadvantage of tin soldering is that the local electroplating of the cold plate 1 is difficult and the corrosion resistance is poor. The disadvantage of interference fit is that the heat pipe 2 is exposed to the outside and a thicker bottom housing is required.

In order to allow the heat pipe 2 to be fixedly embedded in the cold plate 1, an inwardly recessed embedded portion is provided on a side surface of the cold plate 1 and the heat pipe 2 is fixed by the embedded portion, wherein the outer side of the heat pipe 2 does not exceed the opening of the embedded portion, thereby solving the problem in the prior art that the heat pipe 2 is exposed to the outside due to the interference fit. Specifically, as shown in FIG. 1, the embedded portion is an inwardly recessed groove, provided in the side wall of the cold plate 1, extending along the longitudinal direction of the cold plate 1, i.e., the left-right direction as shown in FIG. 1, with the depth of the groove not greater than, i.e., less than or equal to, the thickness of the side wall of the cold plate 1. In the present embodiment, the depth of the groove is preferably less than the thickness of the side wall of the cold plate 1, i.e., the heat pipe 2 is a thin heat pipe 2 with a relatively small thickness. The thickness of the heat pipe 2 is not described and defined in detail, and the heat pipe 2 can be the thin heat pipe 2 available in the market with a relatively small thickness known to those skilled in the art. The depth of the groove can also be small, and accordingly the thickness of the cold plate 1 does not need to be designed to be very thick, which solves the problem that the bottom housing is thick due to the interference fit in the prior art. In a preferable embodiment, in order to protect the heat pipe 2, a cover plate is provided on the outer surface of the heat pipe 2, i.e., at the opening of the groove, for covering the heat pipe 2. In an alternative embodiment, the groove is provided on the inner surface or the outer surface of the cold plate 1 instead of the side wall of the cold plate 1. In the present embodiment, there is a gap between an inner wall of the groove and the heat pipe 2 and the gap is to facilitate the filling of the thermally conductive structural adhesive 4, which is used to make the heat pipe 2 fixedly embedded in the groove.

With regard to the temperature equalization structure layer, a graphite layer 3 is used in the present embodiment. The graphite layer 3 may be formed by stacking multiple layers of graphite sheets, such as graphite paper or graphite heat dissipation sinks common in the prior art, in a vertical direction as shown in FIG. 1. The graphite layer 3 can be designed in various shapes, which are not described and defined in detail and can be selected and designed by those skilled in the art according to actual needs.

The specific performance parameters of the thermally conductive structural adhesive 4 in the present embodiment are not described and defined in detail, and the thermally conductive structural adhesive 4 can be the common thermally conductive structural adhesive 4 available in the existing market and can be selected by those skilled in the art according to actual needs.

Since the LiDAR is installed in a closed space and the housing cannot be in direct contact with the natural air, in order to realize that the heat transferred from the inside of the LiDAR to the housing can be smoothly transferred to the atmosphere, the material of the housing in the present embodiment is designed to be made of semi-solid die-cast aluminum alloy whose thermal conductivity is above 160 W/(m K), which is better than that of ordinary die-cast aluminum alloy (96.2 W/(m K)), and can effectively improve the natural heat dissipation capacity.

In the present embodiment, the chip 6 is connected to the inner surface of the cold plate 1 via a thermally conductive interface material layer 7, and similarly, other components requiring heat dissipation or heat generating components (not shown in the figure) are also connected to the cold plate 1 via the thermally conductive interface material layer 7, and heat is transferred to the cold plate 1 via the thermally conductive interface material layer 7 for heat dissipation. The thermally conductive interface material layer 7 is a conventional thermally conductive interface material available in the existing market, such as a thermally conductive silicone sheet and the specific performance parameters thereof are not described and defined in detail and can be selected by those skilled in the art according to implementation requirements.

The embodiment of the present utility model further provides a LiDAR comprising the LiDAR heat dissipation structure of the embodiment described above. Since the LiDAR heat dissipation structure of the embodiment described above is adopted, the LiDAR has at least the advantages of the LiDAR heat dissipation structure of the embodiment described above.

It should be understood that the detailed description of the embodiments of the present utility model are merely used to illustrate or explain the principle of the present utility model and are not construed as limiting the present utility model. Therefore, any modifications, equivalent substitutions, improvements, etc. without departing from the spirit and scope of the present utility model should be included within the scope of protection of the present utility model. In addition, the appended claims of the present utility model are intended to cover all the variations and modifications that fall within the scope and boundary of the appended claims or equivalents of the scope and boundary.

1. A heat dissipation structure for a light detection and ranging (LiDAR) system, wherein the LiDAR system comprises a mainboard (5), a chip (6), and a housing (8), and the chip (6) is provided on the mainboard (5), the heat dissipation structure comprising:
a cold plate (1), wherein an inner surface of the cold plate is provided with a temperature equalization structure layer attached thereon, and an outer surface of the cold plate facing away from the chip (6) is provided with a plurality of heat dissipation fins or heat dissipation slots formed thereon; and
a heat pipe (2) fixedly embedded in the cold plate (1) through a thermally conductive structural adhesive (4), wherein
the cold plate (1) couples with the housing (8) to form a sealed cavity in which the mainboard and the chip are provided.

2. The heat dissipation structure according to claim 1, wherein:
a recessed embedded portion is provided on a side surface of the cold plate (1),
a gap is formed between an inner wall of the recessed embedded portion and the heat pipe (2), and
the gap is used to be filled with the thermally conductive structural adhesive (4).

3. The heat dissipation structure according to claim 2, wherein:
the recessed embedded portion is a groove extending along a longitudinal direction of the cold plate (1), and
a depth of the groove is no greater than a thickness of a side wall of the cold plate (1).

4. The heat dissipation structure according to claim 2, wherein a cover plate is provided at an opening of the recessed embedded portion for covering the heat pipe (2).

5. The heat dissipation structure according to claim 1, wherein the temperature equalization structure layer is a graphite layer (3).

6. The heat dissipation structure according to claim 5, wherein the graphite layer (3) is formed by stacking multiple layers of graphite sheets.

7. The heat dissipation structure according to claim 1, wherein the housing is made of semi-solid die-cast aluminum alloy.

8. The heat dissipation structure according to claim 1, wherein a thermally conductive interface material layer (7) is provided between the chip (6) and the inner surface of the cold plate (1).

9. A light detection and ranging (LiDAR) system, comprising:
a mainboard (5), a chip (6), and a housing (8), and the chip (6) is provided on the mainboard (5);
a heat dissipation structure comprising:
a cold plate (1), wherein an inner surface of the cold plate is provided with a temperature equalization structure layer attached thereon, and an outer surface of the cold plate facing away from the chip (6) is provided with a plurality of heat dissipation fins or heat dissipation slots formed thereon; and
a heat pipe (2) fixedly embedded in the cold plate (1) through a thermally conductive structural adhesive (4), wherein
the cold plate (1) couples with the housing (8) to form a sealed cavity in which the mainboard and the chip are provided.

10. The LiDAR system according to claim 9, wherein:
a recessed embedded portion is provided on a side surface of the cold plate (1),
a gap is formed between an inner wall of the recessed embedded portion and the heat pipe (2), and
the gap is used to be filled with the thermally conductive structural adhesive (4).

11. The LiDAR system according to claim 10, wherein:
the recessed embedded portion is a groove extending along a longitudinal direction of the cold plate (1), and
a depth of the groove is no greater than a thickness of a side wall of the cold plate (1).

12. The LiDAR system according to claim 10, wherein a cover plate is provided at an opening of the recessed embedded portion for covering the heat pipe (2).

13. The LiDAR system according to claim 9, wherein the temperature equalization structure layer is a graphite layer (3).

14. The LiDAR system according to claim 13, wherein the graphite layer (3) is formed by stacking multiple layers of graphite sheets.

15. The LiDAR system according to claim 9, wherein the housing is made of semi-solid die-cast aluminum alloy.

16. The LiDAR system according to claim 9, wherein a thermally conductive interface material layer (7) is provided between the chip (6) and the inner surface of the cold plate (1).
